(19) United States
(12) Patent Application Publication
(10) Pub. No.: US 2008/0142910 A1
(43) Pub. Date: Jun. 19, 2008

(54) SEMICONDUCTOR DEVICE

(76) Inventor: Yong-Ho Oh, Incheon (KR)

Correspondence Address: SHERR & NOURSE, PLLC, 620 HERNDON PARKWAY, SUITE 200, HERNDON, VA, 20170, US

(21) Appl. No.: 11/931,946

(22) Filed: Oct. 31, 2007

(30) Foreign Application Priority Data
Dec. 19, 2006 (KR) 10-2006-0129997

(51) Int. Cl. H01L 29/78; H01L 21/3205

(52) U.S. Cl. 257/411; 438/591; 257/E29.255; 257/E21.294

(57) ABSTRACT

Embodiments relate to a semiconductor device and fabricating method thereof. In embodiments, a method of fabricating a semiconductor device may include forming a first gate insulating layer on a semiconductor substrate, performing first plasma nitridation on the first gate insulating layer, forming a second gate insulating layer on the first gate insulating layer, performing second plasma nitridation on the second gate insulating layer, forming a gate electrode metal material on the second gate insulating layer, and forming a metal gate electrode pattern by sequentially etching the gate electrode metal material, the second gate insulating layer, and the first gate insulating layer.

The present application claims priority under 35 U.S.C. 119 and 35 U.S.C. 365 to Korean Patent Application No. 10-2006-0129997 (filed on Dec. 19, 2006), which is hereby incorporated by reference in its entirety.

### BACKGROUND

A Metal Oxide Silicon Field Effect Transistor (MOSFET) may consist of a gate electrode, a source electrode, a drain electrode, and a dielectric layer inserted between the gate electrode and the source/drain electrode, and may be constructed on a silicon substrate.

The MOSFET device may be categorized into pMOS (P-channel MOS), nMOS (n-channel MOS), and CMOS types. At one time, pMOS devices were mainly used due to their good power consumption and process control facilitation in integrated circuit fabrication. As device speed became a greater concern, nMOS devices may have become preferred due to their carrier mobility, which may be about 2.5 times faster than hole mobility.

A CMOS device may have various disadvantages. For example, its integration density and complicated fabricating process may be worse than pMOS or nMOS devices. Nevertheless, CMOS devices may have an advantage in that they may have low power consumption.

With respect to device implementation, nMOS circuits may be applied to a memory part of device and CMOS may be applied to a peripheral circuit part.

As down-sizing has become more important, for example requiring lightweight and slim semiconductor devices, a size of a MOSFET may be scaled down. The scaling down of transistors, however, may reduce an effective channel length of a gate electrode, which may lead to a short channel effect. The short channel effect may degrade punch-through characteristic between the source and drain.

MOSFET may use a SiO₂-based gate dielectric and a doped polysilicon gate for 90 nm-devices or below. Accordingly, MOSFETs may have a disadvantage in that gate leakage current may be increased by the scale-down of devices. In addition, a polysilicon gate may have considerable resistance and increased depletion effect. This may cause various limitations in the device.

To overcome such limitations, a gate stack having a metal gate and a high-k dielectric may be employed.

Efforts have been made to research and develop a device that may overcome various problems that may arise due to the substitute for a gate material of the new gate stack. However, many limitations may be put on the high-k dielectric that may require a low thermal budget.

### SUMMARY

Embodiments relate to a semiconductor device, and more particularly, to a semiconductor device and fabricating method thereof. Embodiments may be suitable for a wide scope of applications, and may be particularly suitable for fabricating a CMOS device.

Embodiments may relate to a semiconductor device and fabricating method thereof, by which a gate stack may be provided using a metal gate and a high-k gate dielectric layer having a layered structure in forming a gate electrode.

Embodiments may relate to a semiconductor device and fabricating method thereof, by which problems such as gate leakage current and the like may be enhanced despite employing a gate stack.

Embodiments relate to a semiconductor device and fabricating method thereof, which may apply plasma nitridation to a high-k dielectric layer having a layered structure, which may prevent reactions between insulating layers and may raise a dielectric constant.

According to embodiments, a method of fabricating a semiconductor device may include forming a first gate insulating layer on a semiconductor substrate, performing first plasma nitridation on the first gate insulating layer, forming a second gate insulating layer on the first gate insulating layer, performing second plasma nitridation on the second gate insulating layer, forming a gate electrode metal material on the second gate insulating layer, and forming a metal gate electrode pattern by sequentially etching the gate electrode metal material, the second gate insulating layer, and the first gate insulating layer.

According to embodiments, a semiconductor device may include a semiconductor substrate, and a metal gate electrode pattern including first and second insulating layers having a sandwiched structure formed on the semiconductor substrate, and a gate electrode metal material formed on the second gate insulating layer.

According to embodiments, each of the first and second gate insulating layers may be plasma-nitridated to have a high concentration content. According to embodiments, the plasma-nitridated first gate insulating layer pattern may include SiON formed to be approximately 0˜1 μm thick.

According to embodiments, the second gate insulating layer pattern may include a high-k dielectric belonging to HfSiOₓ series, for example including HfSiO, HfSiON and HfO₂ and the second gate insulating layer pattern may be formed to be approximately 2˜3 nm thick.

According to embodiments, the gate electrode metal material may include one selected from the group consisting of HfN, TaN and TiN, and may be formed to be approximately 50˜80 nm thick. This may reduce sheet resistance thereof.

### DRAWINGS

FIGS. 1A to 1D are cross-sectional diagrams illustrating a semiconductor device and a method of fabricating a semiconductor device according to embodiments.

### DESCRIPTION

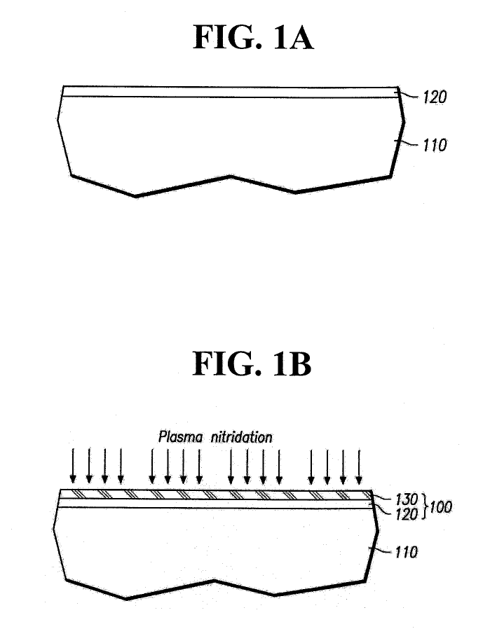

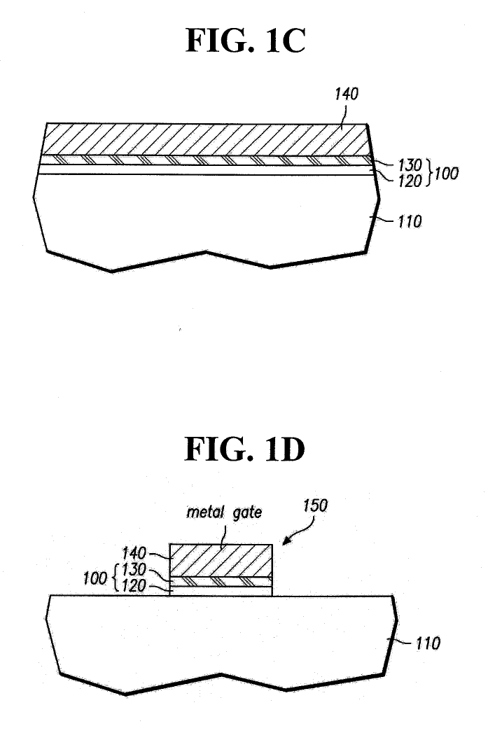

FIGS. 1A to 1D are cross-sectional diagrams for a method of fabricating a semiconductor device according to embodiments. According to embodiments, a process for fabricating a CMOS device is shown.

Referring to FIG. 1, first gate insulating layer 120 may be formed by performing thermal oxidation on semiconductor substrate 110. In embodiments, first gate insulating layer 120 may be formed by growing a silicon oxide (SiO₂) layer, for example by carrying out thermal oxidation on semiconductor substrate 110 of silicon.

In embodiments, first gate insulating layer 120 may be formed to be approximately 0˜1 nm thick. This may prevent a problem that a high-k dielectric comes into contact with silicon (Si) to react with in forming the high-k dielectric on substrate 110. According to embodiments, the high-k dielectric layer may be formed of HfSiOₓ based substance, including, for example, HfO₂ or the like.

First plasma nitridation may then be carried out on first gate insulating layer 120 formed of SiO₂ on substrate 110. In embodiments, the first plasma nitridation may be carried out under process conditions of setting plasma power to approximately 150˜200 W and supplying nitrogen of approximately 1˜10% content for approximately 90˜120 seconds.

The process conditions of the plasma nitridation may be adjustable according to a thickness of first gate insulating layer 120 formed of silicon oxide. In embodiments, the process conditions may be adjustable according to the nitrogen content. In embodiments, the first plasma nitridation may performed to turn first gate insulating layer 120 of SiO₂ into SiON.

According to embodiments, it may be possible to further lower EOT (electrical oxide thickness) through plasma nitridation. According to embodiments, it may be possible to minimize first a reaction between gate insulating layer 120 and high-k second gate insulating layer that may be formed later. For example, nitrogen may be contained in the first gate insulating layer of SiO₂, and a corresponding dielectric constant may be raised to reduce a thickness of first gate insulating layer 120.

Referring to FIG. 1B, second gate insulating layer 130 having a high dielectric constant (high-k) may be formed on first gate insulating layer 120 having undergone the first plasma nitridation. In embodiments, second gate insulating layer 130 may be formed by ALD (atomic layer deposition), which may maintain a small EOT, and may be formed to be approximately 2-3 nm thick using a high-k dielectric. For instance, second gate insulating layer 130 may be formed of a high-k dielectric belong to HfSiOx series including HfSiO, HfSiON, HfO₂ and the like.

According to embodiments, the HfSiOₓ-series insulating layer 130 having a high-k may have a relatively high dielectric constant and may maintain its properties well.

Second plasma nitridation of high concentration may be carried out on the high-k second gate insulating layer 130. In embodiments, the second plasma nitridation may be carried out under the process conditions of setting plasma power to approximately 150˜200 W and supplying nitrogen of approximately 10˜20% content for approximately 90˜120 seconds heavily. By performing the second plasma nitridation, it may be possible to minimize reaction on an interface between high-k second gate insulating layer 130 and a gate electrode metal that may be formed later and may further raise a dielectric constant.

In embodiments, gate insulating layer 100 having a layered structure may be formed on semiconductor (silicon) substrate 110 by stacking first and second gate insulating layers 120 and 130.

Referring to FIG. 1C, gate electrode metal material 140, which may be used to form a gate electrode, may be formed on gate insulating layer 100 having the layered structure including the first and second gate insulating layers 120 and 130 on the semiconductor (silicon) substrate. In embodiments, gate electrode metal material 140 may be formed of one of HfN, TaN and TiN, which may reduce sheet resistance. In embodiments, gate electrode metal material 140 may be formed to be approximately 50˜80 nm thick.

According to embodiments, polysilicon may be replaced by a metal material to form gate electrode metal material 140. This may be done for various reasons.

For example, with respect to a metal gate, depletion may be minimized and may prevent capacitance reduction attributed to an increased thickness of an effective gate oxide layer.

In addition, since impurities may not be used, penetration of impurity such as boron and the like may be possible. For instance, in a p⁺-polysilicon gate electrode, boron used as p-type impurity may penetrate into a lower area.

Moreover, a metal gate may have beneficial properties, such as low resistance and thermal stability.

Referring to FIG. 1D, gate electrode metal material 140, second gate insulating layer 130, and first gate insulating layer 120 may be sequentially etched, for example using a photoresist pattern (not shown in the drawing). In embodiments, metal gate electrode pattern 150 may be formed. In the etching process for forming metal gate electrode pattern 150, the respective layers may be sequentially etched or gate electrode metal material 140, second gate insulating layer 130, and first gate insulating layer 120 may be processed in-situ. The etching process, according to embodiments, may be optimized to prevent a surface of the semiconductor (Si) substrate from being damaged.

According to embodiments, by performing plasma nitridation on each high-k insulating layer configuring a layered structure, inter-insulating layer reaction may be prevented and a dielectric constant may be raised.

In embodiments, by using a metal gate, various problems associated with the related art polysilicon gate may be overcome.

According to embodiments, various effects or advantages may be achieved.

For example, embodiments may lower EOT (electrical oxide thickness) by performing plasma nitridation on each high-k insulating layer configuring a layered structure. Accordingly, it may be possible to minimize a reaction between the insulating layers configuring the layered structure. Moreover, it may be possible to raise their dielectric constants.

In addition, embodiments may include a metal gate, which may reduce gate leakage current that may be generated in a related art polysilicon gate.

Moreover, embodiments may provide a new gate stack including a metal gate and high-k dielectrics configured in a layered structure, which may enhance device performance.

It will be apparent to those skilled in the art that various modifications and variations may be made to embodiments. Thus, it is intended that embodiments cover modifications and variations thereof within the scope of the appended claims. It is also understood that when a layer is referred to as being “on” or “over” another layer or substrate, it may be directly on the other layer or substrate, or intervening layers may also be present.

What is claimed is:

1. A method, comprising:
forming a first gate insulating layer over a semiconductor substrate;
performing a first plasma nitridation to the first gate insulating layer;
forming a second gate insulating layer over the first gate insulating layer;
performing a second plasma nitridation to the second gate insulating layer;
forming a gate electrode metal material over the second gate insulating layer; and
forming a metal gate electrode pattern by etching the gate electrode metal material, the second gate insulating layer, and the first gate insulating layer.

2. The method of claim 1, wherein the first gate insulating layer is formed by growing SiO₂ on the semiconductor substrate by thermal oxidation.

3. The method of claim 1, wherein the first gate insulating layer is formed to have a thickness of 0˜1 nm.

4. The method of claim 1, wherein the first plasma nitridation is performed with plasma power set to 150˜200 W for 90˜120 seconds.

5. The method of claim 1, wherein the first nitridation is performed with a nitrogen content of 1˜10%.

6. The method of claim 1, wherein the second gate insulating layer is formed by ALD (atomic layer deposition).

7. The method of claim 1, wherein the second gate insulating layer is formed to have a thickness of 2˜3 nm using a high-k dielectric.

8. The method of claim 1, wherein the second gate insulating layer comprises a high-k dielectric belonging to HfSiOₓ series.

9. The method of claim 8, wherein the second gate insulating layer comprises one of HfSiO, HfSiON, and HfO₂.

10. The method of claim 1, wherein the second plasma nitridation is performed with plasma power set to 150˜200 W for 90˜120 seconds.

11. The method of claim 1, wherein the second nitridation is performed with a nitrogen content of 10˜20%.

12. The method of claim 1, wherein the gate electrode metal material, the second gate insulating layer, and the first gate insulating layer are etched in-situ to form the metal gate electrode pattern.

13. The method of claim 1, wherein the gate electrode metal material comprises at least one of HfN, TaN, and TiN.

14. The method of claim 1, wherein the gate electrode metal material is formed to have a thickness of 50˜80 nm.

15. A device comprising:
a semiconductor substrate; and
a metal gate electrode pattern including first and second insulating layers having a layered structure over the semiconductor substrate, and a gate electrode metal material formed over the second gate insulating layer.

16. The device of claim 15, wherein each of the first and second gate insulating layers is plasma-nitridated before forming the gate electrode metal.

17. The device of claim 16, wherein the plasma-nitridated first gate insulating layer pattern comprises SiON formed to have a thickness of 0˜1 nm.

18. The device of claim 17, wherein the second gate insulating layer pattern comprises a high-k dielectric belonging to HfSiOₓ series and wherein the second gate insulating layer pattern is formed to have a thickness of 2˜3 nm.

19. The device of claim 18, wherein the second gate insulating layer pattern comprises one of HfSiO, HfSiON and HfO₂.

20. The device of claim 18, wherein the gate electrode metal material comprises at least one of HfN, TaN and TiN, and wherein the gate electrode metal material is formed to have a thickness of 50˜80 nm.
